(19) United States
(12) Patent Application Publication
(10) Pub. No.: US 2008/0197493 A1
(43) Pub. Date: Aug. 21, 2008

(54) Integrated circuit including conductive bumps

(76) Inventor: Stefan Geyer, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/707,427

(22) Filed: Feb. 16, 2007

(51) Int. Cl. H01L 23/48; H01L 21/00

(52) U.S. Cl. 257/738; 438/106; 257/E23.01; 257/E21.001

(57) ABSTRACT

One embodiment provides an integrated circuit including an electrical contact and a conductive bump elongated via centrifugal forces. The conductive bump has a base and a top. The base is attached to the electrical contact and the top remains unattached.

### BACKGROUND

Electronic packaging continues to evolve and impact the electronics industry. The trend toward smaller, lighter, and thinner consumer products requires further packaging miniaturization. Surface-mount technology (SMT) and ball grid array (BGA) packages allow reduction of pad pitch on the printed circuit board. Chip-scale or chip-size packaging (CSP) includes surface mountable packages having areas of no more than 1.2 times the original die area. Wafer-level packaging (WLP) evolved as one type of CSP, where the resulting package is substantially the same size as the die.

WLP refers to packaging an integrated circuit at wafer level, instead of assembling the package of each individual unit after wafer dicing. WLP extends the wafer fabrication process to include device interconnection and device protection processes. Often, in WLP a completely packaged wafer is burned-in and tested after the final packaging step. Tests before packaging are no longer necessary.

Cost, size, wafer level burn-in, and wafer level testing are forces driving the industry toward wafer level solutions. WLP uses fabrication type processing, which decreases cost. WLP delivers die size packages by extending wafer processing through packaging. Also, packaging in fabrication reduces packaging time and inventory, since devices no longer have to be packaged separately between fabrication and assembly.

Typically, a WLP process adds one more level of wiring interconnect to redistribute the peripheral bonding pads to an array. Solder bump pads are arranged above the die circuitry and solder bumps are applied to the solder bump pads. The wafer is diced and each of the packaged die is soldered to a substrate or printed circuit board via the solder bumps.

The packaged die and the printed circuit board have different coefficients of thermal expansion (CTE), which can lead to tears in the solder bumps during temperature cycling of the printed circuit board and the attached packaged die. Solder bumps located on the outside of the packaged die have the largest distance to neutral point (DNP) or distance to the middle of the die and are most susceptible to tearing during temperature cycling. Also, solder bumps located on the outside of larger packaged die are more susceptible to tearing during temperature cycling than solder bumps located on the outside of smaller packaged die.

For these and other reasons there is a need for the present invention.

### SUMMARY

The present disclosure describes an integrated circuit including elongated conductive bumps provided via centrifugal forces. One embodiment provides an integrated circuit including an electrical contact and a conductive bump elongated via centrifugal forces. The conductive bump has a base and a top. The base is attached to the electrical contact and the top remains unattached.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagram illustrating one embodiment of a semiconductor wafer including conductive bumps.

FIG. 2 is a diagram illustrating one embodiment of a centrifugal system.

FIG. 3 is a diagram illustrating one embodiment of a wafer holder and centrifuge drum.

FIG. 4 is a diagram illustrating one embodiment of a wafer including elongated conductive bumps after centrifugal processing.

FIG. 5 is a diagram illustrating one embodiment of a wafer including the elongated conductive bumps and after being coated with a polymer coating.

FIG. 6 is a diagram illustrating one embodiment of integrated circuits from a wafer after dicing the wafer.

FIG. 7 is a flow chart illustrating the process of forming elongated conductive bumps on semiconductor wafers via centrifugal forces.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

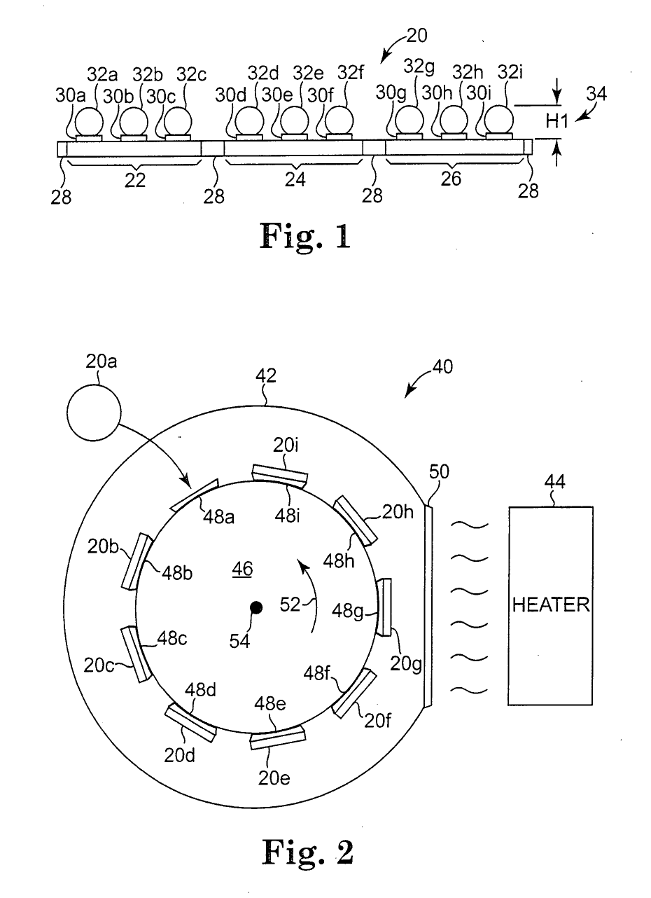

FIG. 1 is a diagram illustrating one embodiment of a semiconductor wafer 20 that includes integrated circuits 22, 24, and 26. Wafer 20 includes spacing areas 28 around the perimeter of wafer 20 and between integrated circuits 22, 24, and 26. Wafer 20 can be any suitable size and include any suitable number of integrated circuits. In one embodiment, wafer 20 is an 8″ wafer.

Wafer 20 includes conductive contacts 30a-30i and conductive bumps 32a-32i. Each of the conductive contacts 30a-30i is electrically coupled to one or more circuits in one of the integrated circuits 22, 24, and 26. Each of the conductive bumps 32a-32i is disposed on and electrically coupled to one of the conductive contacts 30a-30i, respectively. Each of the conductive bumps 32a-32i has a stand-off height H1 at 34, which is the distance from the top of wafer 20 to the top of the conductive bump 32a-32i.

In one aspect of the invention, conductive bumps 32a-32i are elongated via centrifugal force to form elongated conductive bumps. Each of the elongated conductive bumps includes a base attached to one of the conductive contacts 30a-30i and a top that remains unattached during the process of elongating the conductive bump. Wafer 20 is spun in a centrifuge to elongate the conductive bumps 32a-32i. In other embodiments, wafer 20 including conductive bumps 32a-32i is diced or singulated, where each of the singulated integrated circuits 22, 24, and 26 is spun in a centrifuge to elongate conductive bumps 32a-32i.

Wafer 20 is subsequently coated with a polymer coating that surrounds the footprints of the elongated conductive bumps. The polymer coating is applied prior to attaching the tops of the elongated conductive bumps to any substrate or circuit board. The tops of the elongated conductive bumps are at an increased or heightened stand-off height as compared to the stand-off height H1 of non-elongated conductive bumps 32a-32i.

Each of the integrated circuits 22, 24, and 26 includes some of the conductive contacts 30a-30i and some of the conductive bumps 32a-32i. Integrated circuit 22 includes conductive contacts 30a-30c and conductive bumps 32a-32c. Integrated circuit 24 includes conductive contacts 30d-30f and conductive bumps 32d-32f, and integrated circuit 26 includes conductive contacts 30g-30i and conductive bumps 32g-32i. The integrated circuits 22, 24, and 26 are electrically coupled and physically connected to a circuit board via the corresponding conductive bumps 32a-32i.

In one embodiment, before placing conductive bumps 32a-32i on the conductive contacts 30a-30i, each of the conductive contacts 30a-30i is covered with under-bump metallization (UBM). UBM provides a strong, stable, low resistance electrical connection to the integrated circuit and UBM adheres well to aluminum and surrounding passivation layers. Also, UBM provides a barrier to prevent diffusion of other conductive bump metals into integrated circuits 22, 24, and 26 and UBM is readily wettable for solder reflow. In one embodiment, UBM includes multiple layers of different metals, such as an adhesion layer, a diffusion barrier layer, a solderable layer, and an oxidation barrier layer. In one embodiment, UBM includes an adhesion layer of Ti/Cr/Al, a diffusion barrier layer of Cr:CU, a solderable layer of Cu/Ni:V, and an oxidation barrier layer of Au.

In one embodiment, wafer 20 includes redistribution layers (RDL) of alternating passivation and metallization layers. This enables die contact pads to be relocated from their original locations around the edges of integrated circuits 22, 24, and 26 to an area array of pads located over the active area of an integrated circuit die. Pad translation enables legacy designs to be quickly and cost-effectively converted to WLP package configurations

In one embodiment, the conductive bumps 32a-32i are solder bumps. In one embodiment, the conductive bumps 32a-32i are disposed on wafer 20 in a controlled collapse chip connection new process (C4NP), which is a process for forming solder balls on the wafer. In one embodiment, the conductive bumps 32a-32i are disposed on wafer 20 via screen printing. In one embodiment, the conductive bumps 32a-32i are disposed on wafer 20 via plating.

During temperature cycle testing, the reliability of conductive bumps attached between an integrated circuit and a circuit board can be increased by increasing the stand-off height of the conductive bumps. The strain range of a conductive bump, which is a measure of tension in the conductive bump, is given by EQUATION I.

STRAIN RANGE=(ΔCTE*ΔT*DNP/H), EQUATION I

where ΔCTE is the difference in the coefficients of thermal expansion of the integrated circuit and the circuit board, ΔT is the change in the temperature, DNP is the distance to a neutral point, and H is the stand-off height of the conductive bump.

Increasing the stand-off height H decreases the tension in the conductive bump, which reduces cracking of the conductive bump and increases board level reliability. By increasing the stand-off height of the conductive bumps, WLP can be used for larger integrated circuit chips.

FIG. 2 is a diagram illustrating one embodiment of a centrifugal system 40 that is used to elongate conductive bumps on wafers 20a-20i. Each of the wafers 20a-20i is similar to wafer 20 of FIG. 1 and each of the wafers 20a-20i includes conductive bumps, similar to conductive bumps 32a-32i. In other embodiments, each of the wafers 20a-20i can be similar to any suitable wafers including conductive bumps.

Centrifugal system 40 includes a centrifuge 42 and a heater 44. Centrifuge 42 includes a centrifuge drum 46, wafer holders 48a-48i, and a window 50. Centrifuge drum 46 spins, as indicated at 52, around drum axis 54. In one embodiment, drum axis 54 is vertically orientated. In one embodiment, drum axis 54 is horizontally orientated. In one embodiment, drum axis 54 is in any suitable angular orientation.

Each of the wafer holders 48a-48i grasps or holds one of the wafers 20a-20i. In one embodiment, wafer holders 48a-48i hold the wafers 20a-20i via clamps. In one embodiment, wafer holders 48a-48i hold the wafers 20a-20i via tape. In one embodiment, wafer holders 48a-48i hold the wafers 20a-20i electrostatically. In one embodiment, wafer holders 48a-48i hold the wafers 20a-20i via a vacuum.

The conductive bumps on wafers 20a-20i face away from drum axis 54. Heater 44 is situated outside window 50 to radiate heat through window 50 and onto the conductive bumps of each of the wafers 20a-20i as centrifuge drum 46 spins around drum axis 54.

Heater 44 heats the conductive bumps on wafers 20a-20i to melt the conductive bumps as centrifuge drum 46 spins around drum axis 54. The centrifugal force exerted on the melted conductive bumps elongates the conductive bumps to provide increased or heightened stand-off heights. Heater 44 is switched off to cool and solidify the elongated conductive bumps. In one embodiment, heater 44 is a rapid thermal processing (RTP) tool. In one embodiment, heater 44 is an RTP tool that shines light through window 50 to heat the conductive bumps on wafers 20a-20i. In one embodiment, continuous infrared light is shined on centrifuge drum 46 and conductive bumps on wafers 20a-20i.

In operation, each of the wafers 20a-20i is attached to centrifuge drum 46 via one of the wafer holders 48a-48i, respectively. Centrifuge 42 spins centrifuge drum 46 and the attached wafers 20a-20i at a constant number of revolutions per minute. In one embodiment, centrifuge 42 spins centrifuge drum 46 and the attached wafers 20a-20i at a speed in the range of 200-400 revolutions per minute.

Next, heater 44 is switched on to heat and melt the conductive bumps on wafers 20a-20i to a liquefied state. The centrifugal force imparted to the melted conductive bumps elongates the conductive bumps. The spinning speed is chosen to be high enough that the centrifugal force is greater than the gravitational force, such that the conductive bumps are elongated in a radial direction rather than in the direction of the gravitational force. Heater 44 is switched off or turned down to cool and solidify the elongated conductive bumps. In one embodiment, the spinning speed is chosen to provide a centrifugal force of greater than 10 times the gravitational force.

Centrifuge 42 stops spinning centrifuge drum 46 and wafers 20a-20i are unloaded from centrifuge drum 46. The resulting wafers 20a-20i include elongated conductive bumps.

In other embodiments, each of the wafers 20a-20i can be singulated and each of the singulated integrated circuits 22, 24, and 26 is spun via centrifuge 42 to elongate conductive bumps.

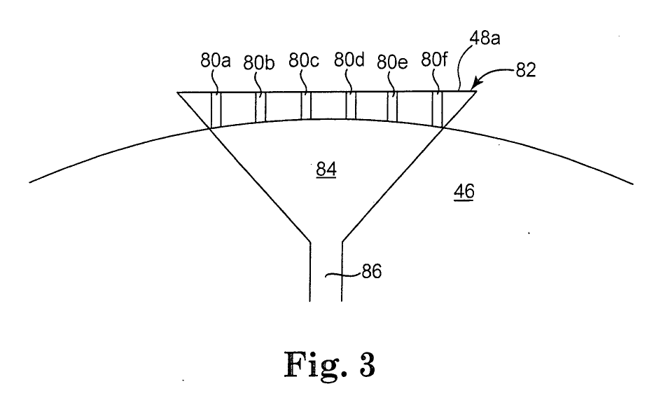

FIG. 3 is a diagram illustrating one embodiment of a wafer holder 48a and centrifuge drum 46. Wafer holder 48a is mounted on centrifuge drum 46 and holds one or more wafers 20 via a vacuum. Wafer holder 48a includes vauum holes 80a-80f that extend from face 82 of wafer holder 48a to a vacuum chamber 84 in centrifuge drum 46. A vacuum source 86 is coupled to vacuum chamber 84 and provides a vacuum in vacuum chamber 84. The vacuum is conveyed through vacuum holes 80a-80f to the face 82 of wafer holder 48a.

The entire surface of a wafer 20 can be evenly pressed against face 82 of wafer holder 48a. Also, the strength of the vacuum can be adjusted based on the rotational speed of centrifuge drum 46 to balance the vacuum force and the centrifugal force acting on an attached wafer 20. The net force on the attached wafer 20 can be reduced to zero during centrifugation.

The attached wafer 20 is held on wafer holder 48a via vacuum force with the conductive bumps facing away from the axis of centrifuge drum 46. With vacuum force, centrifuge 42 can be spun at speeds that exert up to 1000 times the force of gravity or more without breaking the wafer 20. In one embodiment, wafer holder 48a is configured to hold one wafer 20. In one embodiment, wafer holder 48a is configured to hold multiple wafers 20.

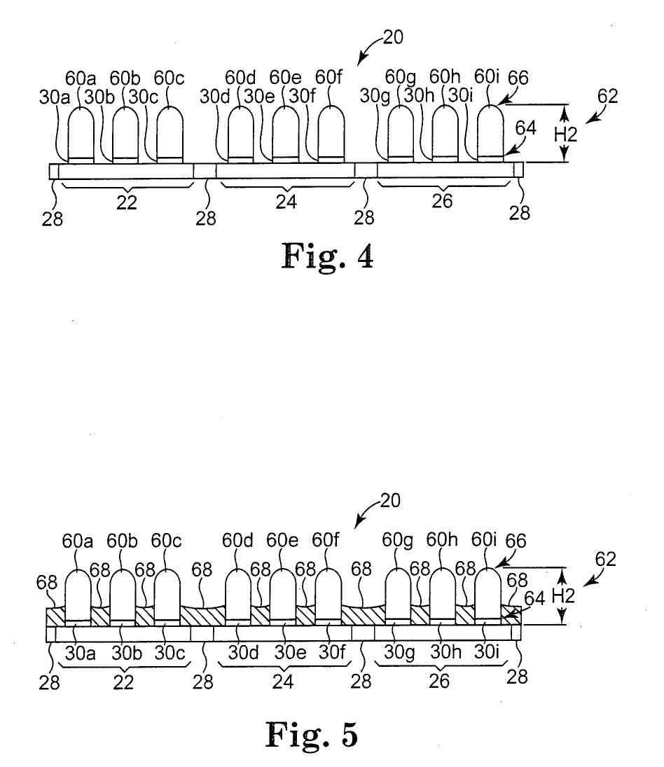

FIG. 4 is a diagram illustrating wafer 20 of FIG. 1 after centrifugal processing via centrifugal system 40 of FIG. 2. The conductive bumps 32a-32i have been elongated via centrifugal forces to create elongated conductive bumps 60a-60i. Each of the elongated conductive bumps 60a-60i has a heightened stand-off height H2 at 62, which is the distance from the top of wafer 20 to the top of the elongated conductive bump 60a-60i. Stand-off height H2 at 62 is greater than stand-off height H1 at 34 (shown in FIG. 1). In one embodiment, the ratio of stand-off height H2 at 62 to the diameter of an elongated conductive bump is substantially 1.5 times. In one embodiment, stand-off height H2 at 62 is substantially 1.5 times greater or more than stand-off height H1 at 34.

Wafer 20 includes the integrated circuits 22, 24, and 26 and spacing areas 28 around the perimeter of wafer 20 and between the integrated circuits 22, 24, and 26. Wafer 20 also includes the conductive contacts 30a-30i. Each of the integrated circuits 22, 24, and 26 includes some of the conductive contacts 30a-30i and some of the elongated conductive bumps 60a-60i. Integrated circuit 22 includes conductive contacts 30a-30c and elongated conductive bumps 60a-60c. Integrated circuit 24 includes conductive contacts 30d-30f and elongated conductive bumps 60d-60f, and integrated circuit 26 includes conductive contacts 30g-30i and elongated conductive bumps 60g-60i. In further processing, the integrated circuits 22, 24, and 26 are electrically coupled and physically connected to a circuit board via the corresponding elongated conductive bumps 60a-60i.

Each of the elongated conductive bumps 60a-60i includes a base, indicated at 64 on elongated conductive bump 60i, and a top, indicated at 66 on elongated conductive bump 60i. The base of each of the elongated conductive bumps 60a-60i is disposed on and electrically coupled to the corresponding one of the conductive contacts 30a-30i. The top of each of the elongated conductive bumps 60a-60i is not attached to any substrate or circuit board during the process of elongating the conductive bumps 32a-32i to form elongated conductive bumps 60a-60i.

FIG. 5 is a diagram illustrating wafer 20 of FIG. 4 after being coated with polymer coating 68. Wafer 20 includes integrated circuits 22, 24, and 26, spacing areas 28, conductive contacts 30a-30i, and elongated conductive bumps 60a-60i, where each of the elongated conductive bumps 60a-60i includes a base, indicated at 64 on elongated conductive bump 60i, and a top, indicated at 66 on elongated conductive bump 60i. The base of each of the elongated conductive bumps 60a-60i is disposed on and electrically coupled to the corresponding one of the conductive contacts 30a-30i. The tops of the elongated conductive bumps 60a-60i are at the increased or heightened stand-off height H2 at 62.

Polymer coating 68 is disposed on wafer 20 prior to attaching the tops of the elongated conductive bumps 60a-60i to a substrate or circuit board. Polymer coating 68 is a fixed polymer coating disposed on wafer 20 in any suitable process. In one embodiment, polymer coating 68 is disposed on wafer 20 in a process that includes dispensing the polymer onto the wafer 20, centrifuging the wafer 20, annealing the wafer 20, and burning elongated conductive bumps 60a-60i free of contaminates via an oxygen plasma burn. In one embodiment, polymer coating 68 includes dispensing benzocyclobutane (BCB) onto the wafer 20. In one embodiment, polymer coating 68 includes polyimide (PI).

Polymer coating 68 is disposed on wafer 20 and surrounds conductive contacts 30a-30i and elongated conductive bumps 60a-60i. In one aspect, polymer coating 68 is disposed around the footprints of elongated conductive bumps 60a-60i. In one aspect, polymer coating 68 is disposed around elongated conductive bumps 60a-60i and polymer coating 68 substantially wicks up the sides of elongated conductive bumps 60a-60i. Polymer coating 68 is used to maintain the heightened stand-off height H2 at 62 and pillar or columnar structure of elongated conductive bumps 60a-60i when the integrated circuits 22, 24, and 26 are connected, such as with soldering, to a substrate or circuit board. While use of polymer coating 68 tends to maximize stand-off height H2 during and after soldering integrated circuits 22, 24, and 26 to a substrate, the stand-off height H2 is increased without polymer coating 68.

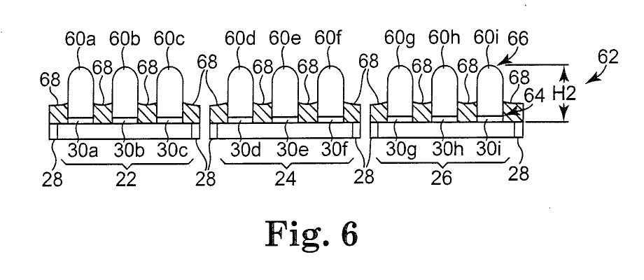

FIG. 6 is a diagram illustrating integrated circuits 22, 24, and 26 from wafer 20 of FIG. 5 after dicing wafer 20. Each of the integrated circuits 22, 24, and 26 includes spacing areas 28, wafer coating 68, some of the conductive contacts 30a-30i, and some of the elongated conductive bumps 60a-60i. Integrated circuit 22 includes conductive contacts 30a-30c and elongated conductive bumps 60a-60c. Integrated circuit 24 includes conductive contacts 30d-30f and elongated conductive bumps 60d-60f, and integrated circuit 26 includes conductive contacts 30g-30i and elongated conductive bumps 60g-60i.

Each of the elongated conductive bumps 60a-60i includes a base, indicated at 64 on elongated conductive bump 60i, and a top, indicated at 66 on elongated conductive bump 60i. The base of each of the elongated conductive bumps 60a-60i is disposed on and electrically coupled to the corresponding one of the conductive contacts 30a-30i. The tops of the elongated conductive bumps 60a-60i are at the increased or heightened stand-off height H2 at 62.

Polymer coating 68 surrounds conductive contacts 30a-30i and elongated conductive bumps 60a-60i. The integrated circuits 22, 24, and 26 are electrically coupled and physically connected to a substrate or circuit board via the corresponding elongated conductive bumps 60a-60i. Polymer coating 68 maintains the heightened stand-off height H2 at 62 and pillar or columnar structure of elongated conductive bumps 60a-60i when the integrated circuits 22, 24, and 26 are connected, such as with soldering, to the substrate or circuit board. In other embodiments, wafer 20 is not diced and the entire wafer is connected to another substrate or circuit board via the elongated conductive bumps 60a-60i.

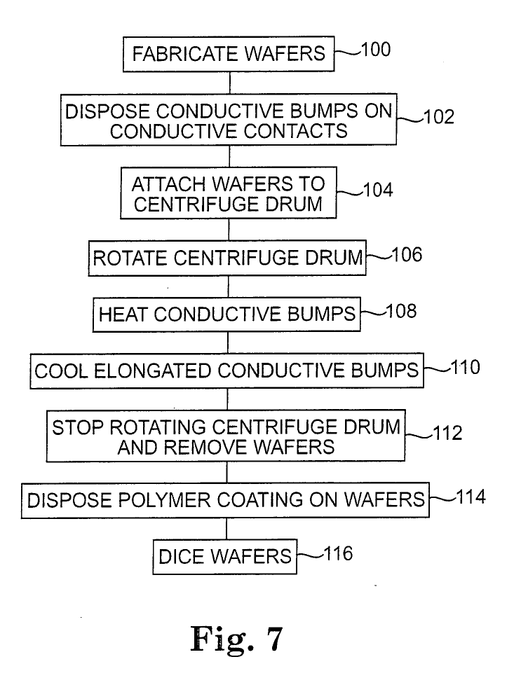

FIG. 7 is a flow chart illustrating the process of forming elongated conductive bumps, such as elongated conductive bumps 60a-60i, on semiconductor wafers, such as wafer 20. At 100, semiconductor wafers are fabricated to have integrated circuits, such as integrated circuits 22, 24, and 26, and spacing areas, such as spacing area 28. Conductive contacts, such as conductive contacts 30a-30i, are fabricated on each of the integrated circuits. In one embodiment, each of the conductive contacts includes UBM. In one embodiment, the integrated circuits include RDL of alternating passivation and metallization layers.

At 102, conductive bumps, such as conductive bumps 32a-32i, are disposed on the conductive contacts. Each of the conductive bumps has a stand-off height H1, which is the distance from the top of the wafer to the top of the conductive bump. In one embodiment, the conductive bumps are solder bumps disposed on the conductive contacts in a C4NP process.

At 104, wafers including the conductive bumps are loaded into a centrifuge and attached to the centrifuge drum. The wafers are loaded with the conductive bumps facing away from the axis of the centrifuge. At 106, the centrifuge is started and the centrifuge drum, including the attached wafers, is spun at a constant speed around the axis of the centrifuge. In one embodiment, the speed of the centrifuge drum, including the attached wafers, is varied according to at least one of processing time and heat on the bumps.

At 108, a heater is switched on to heat the conductive bumps on the wafers as the wafers spin around the axis of the centrifuge. The heat melts the conductive bumps and the centrifugal force elongates the conductive bumps. Since the centrifugal force is much stronger than the gravitational force, the elongated conductive bumps are substantially perpendicular to the axis of the centrifuge. At 110, the heater is switched off to cool and solidify the elongated conductive bumps. The tops of the elongated conductive bumps are at an increased or heightened stand-off height H2, as compared to the stand-off height H1 of non-elongated conductive bumps.

At 112, the rotating centrifugal drum is stopped and the wafers are detached or removed from the drum. At 114, the wafers can be coated with a polymer coating that surrounds the elongated conductive bumps. The polymer coating is applied prior to attaching the tops of the elongated conductive bumps to any substrate or circuit board. Optionally, at 116, the wafers are diced into the individual integrated circuit die.

The polymer coating maintains the heightened stand-off height H2 and pillar or columnar structure of elongated conductive bumps when the integrated circuits or wafers are connected, such as with soldering, to a substrate or circuit board. Increasing the stand-off heights decreases tension in the conductive bumps, which reduces cracking of the conductive bumps and increases board level reliability. By increasing the stand-off heights of the conductive bumps, flip-chip bonding can be used for larger integrated circuit chips.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit, comprising:
an electrical contact; and
a conductive bump elongated via centrifugal forces to have a base and a top, wherein the base is attached to the electrical contact and the top remains unattached during application of the centrifugal forces.

2. The integrated circuit of claim 1, comprising:
a polymer coating disposed around the footprint of the base of the conductive bump.

3. The integrated circuit of claim 2, wherein the polymer coating is configured to improve shear strength between the conductive bump and the electrical contact.

4. The integrated circuit of claim 2, wherein the conductive bump provides a heightened stand off height and the polymer coating is configured to maintain the heightened stand off height of the conductive bump during installation of the integrated circuit.

5. The integrated circuit of claim 1, wherein the integrated circuit is part of a wafer.

6. The integrated circuit of claim 1, wherein the conductive bump comprises a solder bump.

7. A semiconductor packaging system, comprising:
a wafer; and
elongated solder bumps attached to the wafer while centrifugal forces act on the wafer and solder to provide the elongated solder bumps.

8. The semiconductor packaging system of claim 7, comprising:
a polymer coating disposed on the wafer and around the elongated solder bumps.

9. The semiconductor packaging system of claim 8, wherein the elongated solder bumps provide heightened stand off heights and the polymer coating is configured to maintain the heightened stand off heights of the elongated solder bumps during soldering.

10. The semiconductor packaging system of claim 7, wherein the solder is heated via rapid thermal processing techniques while centrifugal forces act on the wafer and the solder to provide the elongated solder bumps.

11. An integrated circuit, comprising:
means for making electrical contact to circuits in the integrated circuit; and
means for connecting the integrated circuit to other circuits, which is elongated via centrifugal force and has a base attached to the means for making electrical contact and a top that is unattached and at a heightened stand off height.

12. The integrated circuit of claim 11, comprising:
means for maintaining the heightened stand off height during installation of the integrated circuit.

13. A packaging system, comprising:
means for disposing solder bumps on a wafer; and
means for spinning the wafer to form elongated solder bumps having bases attached to the wafer and tops that are unattached.

14. The packaging system of claim 13, comprising:
means for heating the solder bumps while spinning the wafer.

15. The packaging system of claim 13, comprising:
means for solidifying the elongated solder bumps.

16. The packaging system of claim 13, comprising:
means for applying a polymer coating on the wafer and around the elongated solder bumps.

17. A method of packaging, comprising:
disposing solder bumps on a wafer; and
spinning the wafer via a centrifuge to form elongated solder bumps having bases attached to the wafer and tops that are unattached while spinning the wafer.

18. The method of claim 17, comprising:
heating the solder bumps while spinning the wafer.

19. The method of claim 18, wherein heating the solder bumps comprises:
heating the solder bumps via rapid thermal processing techniques.

20. The method of claim 17, comprising:
cooling the elongated solder bumps.

21. The method of claim 17, comprising:
disposing a polymer coating around the bases of the elongated solder bumps.

22. The method of claim 21, wherein disposing a polymer coating around the bases of the elongated solder bumps, comprises:
disposing the polymer coating on the wafer via one of spin coating and spraying.

23. The method of claim 17, wherein disposing solder bumps on a wafer comprises;
disposing solder bumps on the wafer via a controlled collapse chip connection new process.

24. The method of claim 17, wherein disposing solder bumps on a wafer comprises;
disposing solder bumps on the wafer via at least one of screen printing and plating.

25. The method of claim 17, wherein spinning the wafer comprises:
spinning the wafer to a constant rotational speed.

26. A method of packaging, comprising:
disposing solder bumps on a wafer;
spinning the wafer via a centrifuge;
heating the solder bumps while spinning the wafer to elongate the solder bumps and provide elongated solder bumps;
cooling the elongated solder bumps; and
applying a polymer coating on the wafer and around the elongated solder bumps.

27. The method of claim 26, wherein spinning the wafer comprises:
spinning the wafer to a constant rotational speed.

28. The method of claim 26, wherein disposing solder bumps on a wafer comprises;
disposing solder bumps on the wafer via a controlled collapse chip connection new process.
